(19) United States
(12) Patent Application Publication
(10) Pub. No.: US 2026/0047001 A1
(43) Pub. Date: Feb. 12, 2026

(54) MOUNTING SUBSTRATE AND MOUNTING STRUCTURE

(71) Applicant: Murata Manufacturing Co., Ltd., Nagaokakyo-shi (JP)

(72) Inventors: Yuji KOBAYASHI, Nagaokakyo-shi (JP); Toshikazu KATO, Nagaokakyo-shi (JP)

(73) Assignee: Murata Manufacturing Co., Ltd., Nagaokakyo-shi (JP)

(21) Appl. No.: 19/363,695

(22) Filed: Oct. 21, 2025

Related U.S. Application Data
(63) Continuation of application No. PCT/JP2024/011735, filed on Mar. 25, 2024.

(30) Foreign Application Priority Data
Apr. 27, 2023 (JP) 2023-073579

(51) Int. Cl. H05K 1/02; H05K 1/11; H05K 1/18

(52) U.S. Cl. CPC H05K 1/0271; H05K 1/111; H05K 1/181; H05K 2201/09072; H05K 2201/09381; H05K 2201/10015; H05K 2201/10522; H05K 2201/10636

(57) ABSTRACT

A mounting substrate includes two wiring patterns and corresponding two lands for mounting a component. A direction connecting centers of two lands in a plan view is a first direction thereto. A slit is provided within a first wiring pattern adjacent to a first land. A length of the slit is greater than a length of a first land in a second direction. A length of the slit is greater than a length of the first land in the first direction. A distance between an end part of the slit and an end part of the first wiring pattern adjacent the first land is less than the length of the first land. The length of a linear end part of the first wiring pattern is equal to or greater than the length of the first land and is in contact with the first land.

### CROSS-REFERENCE TO RELATED APPLICATIONS

This is a continuation application of PCT International Application No. PCT/JP2024/011735 filed on Mar. 25, 2024, designating the United States of America, which claims priority to Japanese patent application JP 2023-073579, filed Apr. 27, 2023, the entire contents of each of which being incorporated herein by reference.

### TECHNICAL FIELD

The present disclosure relates to a mounting board and a mounting configuration, and more specifically, to a mounting board including a wiring pattern of a predetermined shape and a land, and a mounting configuration using the same.

### BACKGROUND ART

In general, in a mounting board on which an IC or an LSI (integrated circuit) is mounted, a bypass capacitor is used for the purpose of absorbing load fluctuation and removing noise during the operation of the IC or the like. The bypass capacitor is connected between a ground wiring pattern for supplying a ground potential and a power supply wiring pattern for supplying a power supply potential via a land.

However, a multilayer ceramic capacitor used as a bypass capacitor may be mounted and connected to a land connected to a so-called solid wiring pattern formed by solid coating a ground wiring pattern or a power wiring pattern as shown in FIG. 4 for voltage stability or handling a large current circuit. When the multilayer ceramic capacitor is mounted on a land connected to a solid wiring pattern, a large mechanical stress is generated in the multilayer ceramic capacitor when the mounting board is bent, which may cause breakage of a bonding portion or cracks in a dielectric constituting the multilayer ceramic capacitor.

When a failure occurs in the bypass capacitor connecting the ground potential and the power supply potential, not only will the function as the bypass capacitor not be exhibited, but also when a short circuit occurs, an excessive current will flow and damage the circuit. For this reason, there is a technique of arranging a plurality of multilayer ceramic capacitors as bypass capacitors (e.g., Patent Document 1), but arranging a plurality of multilayer ceramic capacitors leads to an increase in the size of a mounting board and an increase in cost, and thus is not always an effective means.

Therefore, there is a need to develop mounting boards that are each able to effectively prevent failure of a multilayer ceramic capacitor on the mounting board and stably and reliably install the multilayer ceramic capacitor.

### CITATION LIST

### Patent Document

Patent Document 1: Japanese Unexamined Patent Application, Publication No. 2021-68757

### SUMMARY

### Problems to be Solved

The present disclosure is directed to providing mounting boards that are each able to effectively prevent failure of a multilayer ceramic capacitor on the mounting board and stably and reliably install the multilayer ceramic capacitor, and a mounting configuration using the same.

### Means for Solving the Problems

The present inventors have found that, when a slit is provided in a first wiring pattern for supplying a ground potential or a power supply potential and a size of the slit and a size of a first land in contact with the first wiring pattern are in a predetermined relationship, failure of a multilayer ceramic capacitor in a mounting board may be prevented.

That is, an embodiment provides a mounting board which includes two wiring patterns for respectively supplying a ground potential and a power supply potential, and two lands for connecting each of a pair of terminals of a capacitor to a corresponding one of the two wiring patterns. In a plan view from a direction perpendicular to a surface of the mounting board, when a direction connecting centers of the two lands is defined as a first direction and a direction perpendicular to the first direction is defined as a second direction, a slit is provided in a first wiring pattern, a length of the slit in the second direction is longer than a length of a first land in the second direction, a length of the slit in the first direction is longer than a length of the first land in the first direction, a distance between an end portion among both end portions of the slit in the first direction that is adjacent to the first land and an end portion among both end portions of the first wiring pattern in the first direction that is adjacent to the first land is shorter than the length of the first land in the first direction, and the first wiring pattern has a linear end portion along the second direction, a length of the linear end portion is equal to or longer than the length of the first land in the second direction, and the linear end portion is in contact with the first land.

### Effects

According to an embodiment, mounting boards may be provided that are each able to effectively prevent a failure of a multilayer ceramic capacitor on the mounting board and stably and reliably install the multilayer ceramic capacitor, and a mounting configuration using the same.

### BRIEF DESCRIPTION OF THE DRAWINGS

FIG. 1 is a schematic plan view of a mounting board 1 according to a first embodiment.

FIG. 2 is a schematic plan view of a mounting board 1 according to a second embodiment.

FIG. 3 is a schematic plan view of a mounting board 1 according to a third embodiment of the present invention.

FIG. 4 is a schematic plan view showing a conventional mounting board.

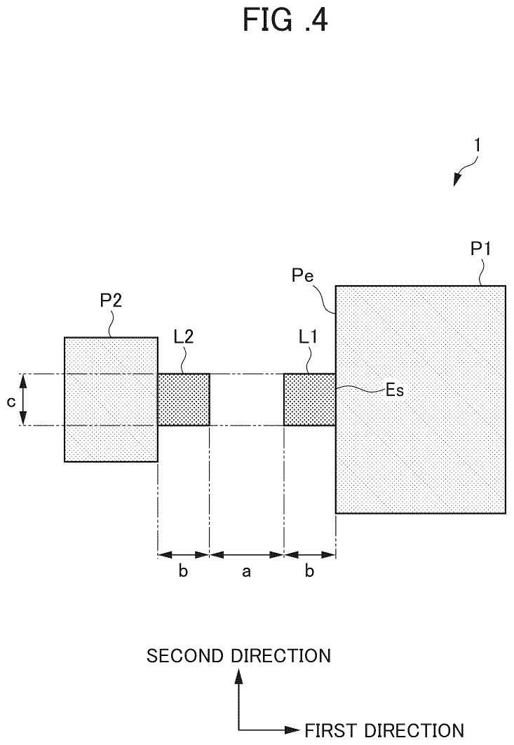

FIG. 5 is an external view of a multilayer ceramic capacitor.

FIG. 6 is a diagram showing a method of a comparative test.

FIG. 7 is a diagram showing a method of a comparative test.

FIG. 8 is a graph showing the results of a comparative test.

FIG. 9 is a graph showing the results of a comparative test.

### DETAILED DESCRIPTION

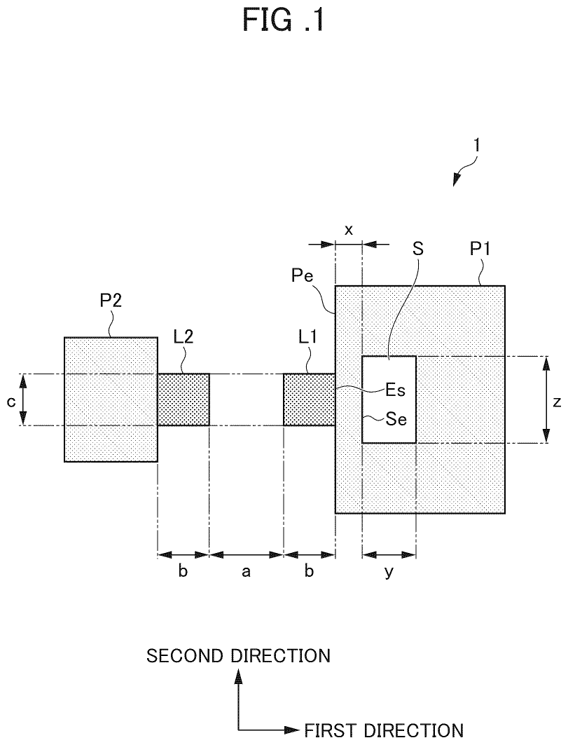

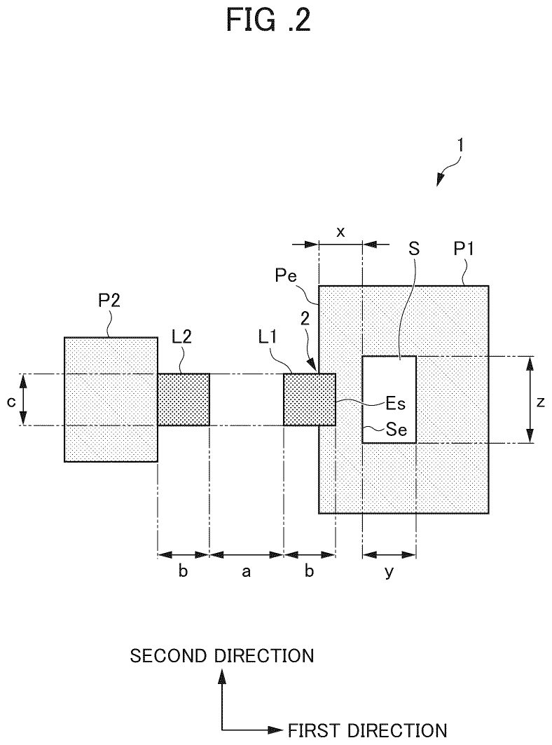

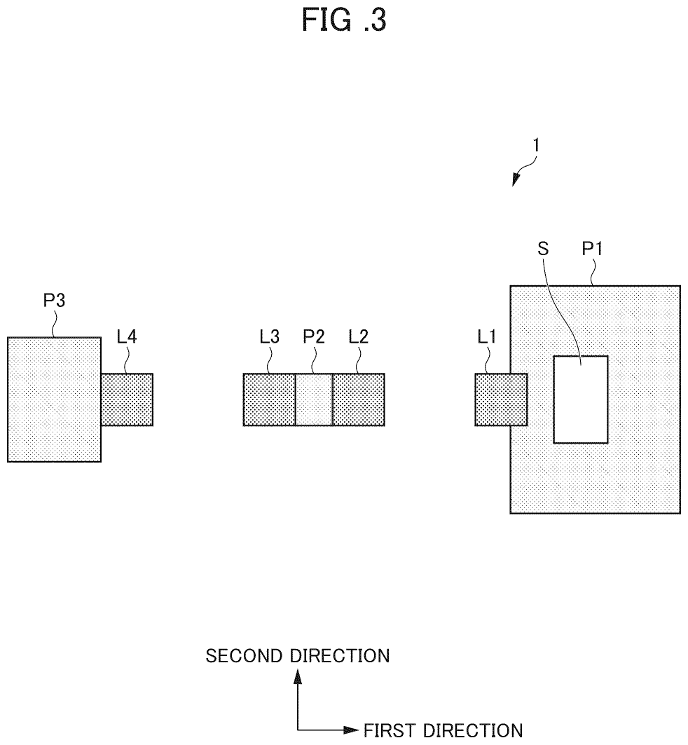

Hereinafter, an embodiment of the mounting board 1 will be described. FIG. 1 is a schematic plan view of a first embodiment. FIG. 2 is a schematic plan view of the second embodiment. FIG. 3 is a schematic plan view of a third embodiment.

While certain embodiments are described, these embodiments are presented by way of example only, and are not intended to limit the scope of the disclosure. Further, contents described in different embodiments may be combined, and such implementations are also included in the present disclosure. In addition, the drawings are for helping understanding of the specification and may be schematically drawn, and the drawn components or the ratio of the dimensions between the components may not coincide with the ratio of the dimensions described in the specification. In addition, components described in the specification may be omitted in the drawings or may be drawn with the number of components omitted.

A mounting board 1 is a board for mounting an IC, an LSI (integrated circuit), or the like. The mounting board 1 includes two wiring patterns for supplying a ground potential and a power supply potential. When an IC or the like is mounted, the IC or the like is connected to a ground wiring pattern to which the ground potential of the mounting board 1 is supplied and a power supply wiring pattern to which the power supply potential is supplied. Further, in order to place the multilayer ceramic capacitor between the ground wiring pattern and the power wiring pattern, two lands for connecting a pair of external electrodes of the multilayer ceramic capacitor to the ground wiring pattern and the power wiring pattern are provided. In addition, the mounting board 1 can be widely used as a board of a capacitor, not limited to multilayer ceramic capacitors and can be used by connecting a pair of terminals corresponding to the pair of external electrodes of a multilayer ceramic capacitor to two lands. Hereinafter, for clarity, one of the two wiring patterns will be referred to as the ‘first wiring pattern’ (P1) and the other as the ‘second wiring pattern’ (P2). Correspondingly, the land connected to the first wiring pattern will be the ‘first land’ (L1), and the land connected to the second wiring pattern will be the ‘second land’ (L2).”

### First Embodiment

A first embodiment of the mounting board 1 will be described. In addition, in order to specify the configuration of the embodiment, a direction connecting centers of two lands in a plan view from a direction perpendicular to the surface of the mounting board 1 is defined as a first direction, and a direction perpendicular to the first direction is defined as a second direction.

The mounting board 1 includes a ground wiring pattern for supplying a ground potential and a power supply wiring pattern for supplying a power supply potential. The ground wiring pattern is a conductor film on which a conductor for supplying a ground potential is printed, the power supply wiring pattern is a conductor film on which a conductor for supplying a power supply potential is printed, and an insulating film (generally a green film) is provided on both surfaces of the conductor films. In the mounting board 1, either the ground wiring pattern or the power supply wiring pattern may be the first wiring pattern P1, and a slit S may be provided in the first wiring pattern P1. However, since the ground wiring pattern is generally larger in area than the power supply wiring pattern, it is preferable that the ground wiring pattern is the first wiring pattern and the slit S is provided in the first wiring pattern P1.

The slit S can be formed by providing a region where a conductor is not printed in the first wiring pattern P1, e.g., the slit is within the conductive material of the first wiring pattern that is void of the conductive material. However, a through hole penetrating the mounting board may be provided in the region of the first wiring pattern P1, and such a through hole may be used as the slit S. FIG. 1 shows a square slit S. However, the present disclosure is not limited to this, and any shape such as a polygonal shape or a circular shape can be adopted.

The first land L1 and the second land L2 are conductor films for soldering a mounting component such as a multilayer ceramic capacitor, and are usually made of copper foil. Unlike the first wiring pattern P1, an insulating film is not provided on the surfaces of the first land L1 and the second land L2. In FIG. 1, a first land L1 and a second land L2 both having a rectangular shape are shown, but the shapes are not limited thereto.

The length z of the slit S in the second direction is longer than the length c of the first land L1 in the second direction. Since both the slit S and the first land L1 shown in FIG. 1 are quadrangular, the length z and the length c are equal to the lengths of the sides of the slit S and the first land of the quadrangular shape extending in the second direction, respectively. However, in a case where the slit S or the first land L1 is a circle, a polygon, or the like other than the quadrangular shape, the length z of the slit S in the second direction is defined as the length of the longest portion of the outer shape of the slit S in the second direction in a plan view from the direction perpendicular to the surface of the mounting board 1. Similarly, the length c of the first land L1 in the second direction is defined as the length of the longest portion of the outer shape of the first land L1 in the second direction in a plan view from the direction perpendicular to the surface of the mounting board 1.

When the length z of the slit S in the second direction is two times or more the length c of the first land in the second direction, mounting of the multilayer ceramic capacitor on the mounting board 1 becomes more stable.

The length y of the slit S in the first direction is longer than the length b of the first land L1 in the first direction. Since both the slit S and the first land L1 shown in FIG. 1 are quadrangular, the length y and the length b are equal to the lengths of the sides of the slit S and the first land of the quadrangular shape extending in the first direction, respectively. However, in a case where the slit S or the first land L1 is a circle, a polygon, or the like other than the quadrangular shape, the length y of the slit S in the first direction is defined as the length of the longest portion of the outer shape of the slit S in the first direction in a plan view from the direction perpendicular to the surface of the mounting board 1. Similarly, the length b of the first land L1 in the first direction is defined as the length of the longest portion of the outer shape of the first land L1 in the first direction in a plan view from the direction perpendicular to the surface of the mounting board 1.

The distance x between an end portion Se among both end portions of the slit S in the first direction which is adjacent to the first land L1 and an end portion Pe among both end portions of the first wiring pattern in the first direction which is adjacent to the first land L1 is shorter than the length b of the first land in the first direction.

The first wiring pattern P1 has a linear end portion Es along the second direction. The length of the linear end portion Es is equal to or longer than the length c of the first land L1 in the second direction. The first land L1 is in contact, e.g., direct contact, with the linear end portion Es.

When the multilayer ceramic capacitor 10 is mounted on such a mounting board 1, a mounting configuration is formed in which the first external electrode 31 and the second external electrode 32 of the multilayer ceramic capacitor 10 are respectively connected to the first land L1 and the second land L2 for connecting the first wiring pattern P1 and the second wiring pattern P2.

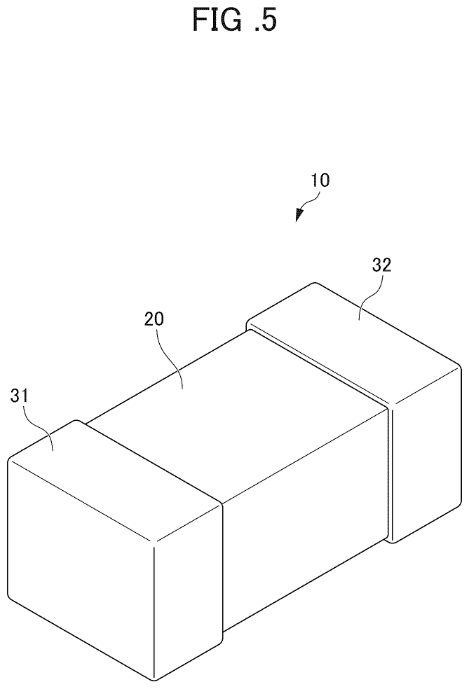

As shown in FIG. 5, the multilayer ceramic capacitor 10 includes a multilayer body 20 having a configuration in which a plurality of dielectric layers and a plurality of internal electrode layers are laminated, and the first external electrode 31 and the second external electrode 32 provided on opposite outer surfaces of the multilayer body 20. The internal electrode layers adjacent to each other in the lamination direction are alternately connected to the first external electrode 31 and the second external electrode 32 which are different from each other, and a voltage is applied to the first external electrode 31 and the second external electrode 32 to generate a capacitance in the multilayer body 20.

When the mounting board 1 on which the multilayer ceramic capacitor 10 is mounted is bent in a convex shape, the surface of the board extends in a horizontal direction, and the space between the lands is deformed to be spread. This deformation becomes a force for separating the first external electrode 31 and the second external electrode 32 of the multilayer ceramic capacitor 10 soldered to the first land L1 and the second land L2, respectively, and causes cracks in the dielectric constituting the multilayer ceramic capacitor 10. The solid wiring has a higher rigidity than the board, and when the board is bent in a convex shape, the distortion of the surface of the board is concentrated between the lands which are areas not covered with the solid wiring, such that a larger tensile stress is generated in the dielectric of the multilayer ceramic capacitor. When the slit S is formed in the first wiring pattern P1 as in the mounting board 1, the distortion of the board surface is dispersed in the slit S, such that the tensile stress generated in the multilayer ceramic capacitor 10 may be reduced by reducing the distortion of the board surface between the first land L1 and the second land L2.

The following Comparative Tests are provided in order to highlight characteristics of one or more embodiments, but it will be understood that the Comparative Tests are not to be construed as limiting the scope of the embodiments, nor are the Comparative Tests to be construed as being outside the scope of the embodiments.

### Comparative Tests

As samples, a conventional mounting board without any slit and a plurality of mounting boards 1 provided with slits S of various sizes were prepared, and the relationship between the length z of the slit S provided in the first wiring pattern P1 in the second direction and the stress generated when the mounting board 1 was bent was measured by FEN analysis.

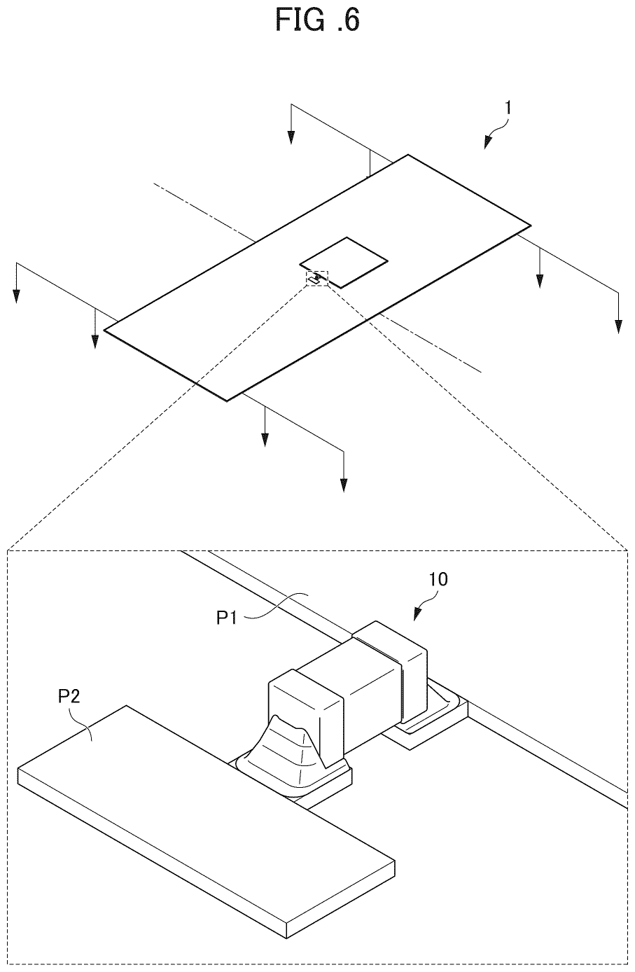

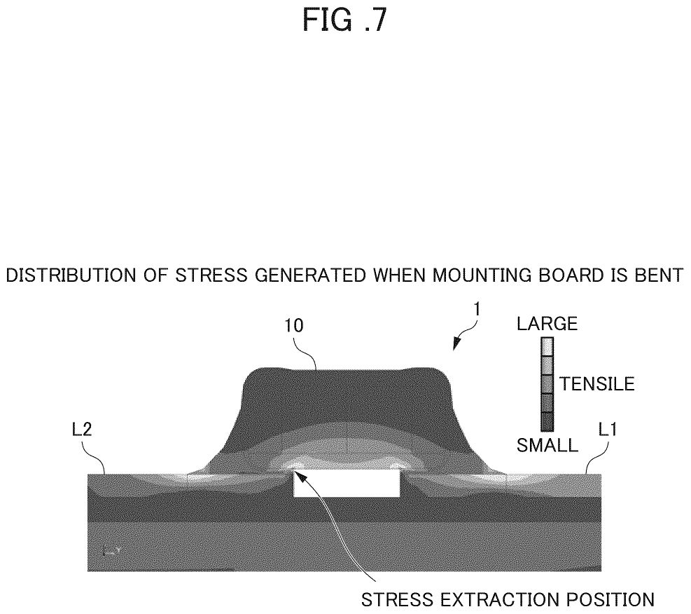

In the comparative tests, as shown in FIG. 6, the mounting board 1 is bent in a convex shape by pressing down at a position at an equal distance from the multilayer ceramic capacitor 10 in the first direction with the multilayer ceramic capacitor 10 as the center. The distribution of the stress generated at this time is shown in FIG. 7. In FIG. 7, the stress was analyzed for the upper portion of the side edge at which the first land L1 and the second land L2 are opposed to each other, where the multilayer ceramic capacitor 10 and the first land L1 or the multilayer ceramic capacitor 10 and the second land L2 are bonded to each other and the stress is most likely to concentrate.

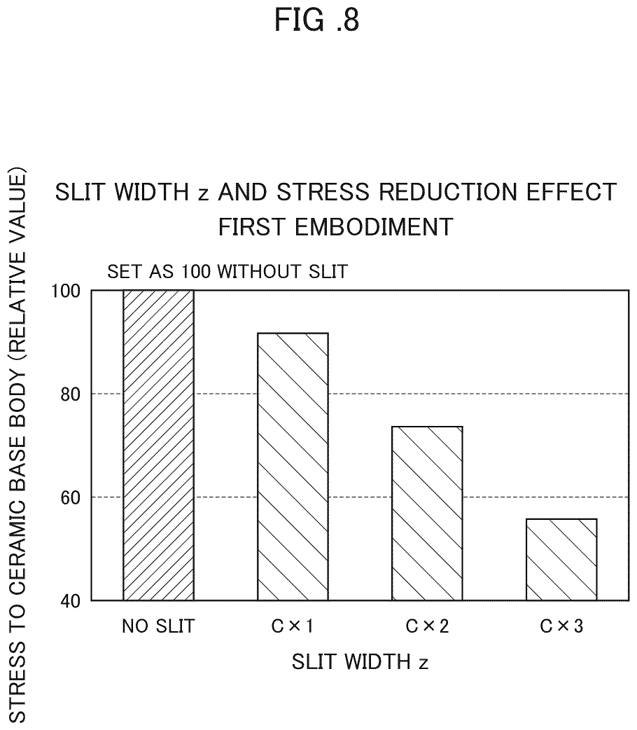

As shown in FIG. 8, the stress is relaxed by forming the slit S in the first wiring pattern P1; however, it was confirmed as an advantageous effect that it is possible to enhance the effect of relaxing the stress by further increasing the length z of the slit S in the second direction. In FIG. 8, the length z of the slit S in the second direction is indicated by the multiplier of the length c of the first land L1 in the second direction.

### Second Embodiment

A second embodiment of the mounting board 1 will be described. In the second embodiment, a configuration different from that of the first embodiment will be mainly described.

In the second embodiment, as shown in FIG. 2, a recessed portion 2 is formed in the first wiring pattern P1. The first wiring pattern P1 has a linear end portion Es along the second direction, and the first land L1 is in contact, e.g., direct contact, with the linear end portion Es. In the second embodiment, at least a portion of the first land L1 is provided in the recessed portion 2.

In each of the first embodiment and the second embodiment, an example in which the slit S is provided in the first wiring pattern P1 is shown. However, a similar slit may be provided in the second wiring pattern P2 instead of or in addition to the slit S in the first wiring pattern. That is, in the mounting board 1, a first slit may be in the first wiring pattern P1 and a second slit may be in the second wiring pattern P2.

### Comparative Tests

Similarly to the first embodiment, in the second embodiment, the relationship between the length z of the slit S provided in the first wiring pattern P1 in the second direction and the stress generated when the mounting board 1 is bent was measured by FEN analysis.

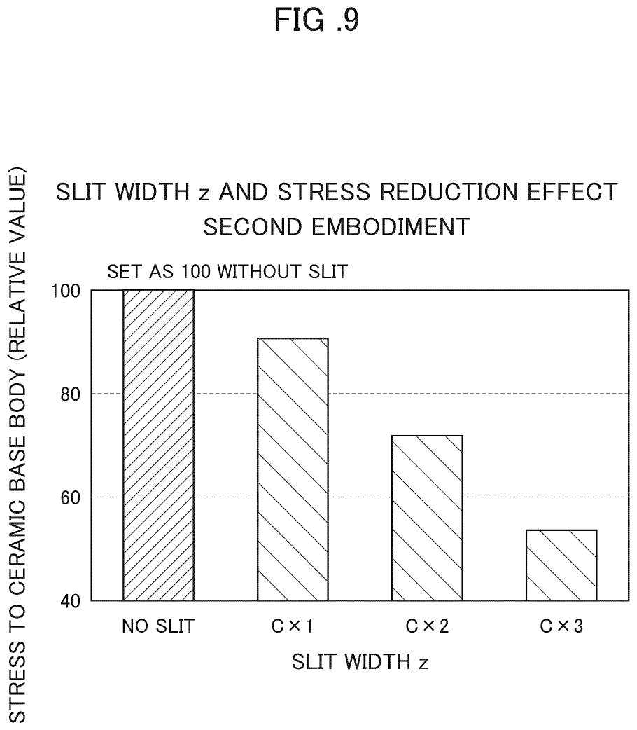

As shown in FIG. 9, in the second embodiment, similarly to the first embodiment, when the slit S is formed in the first wiring pattern P1, the stress is relaxed, and it was confirmed as an advantageous effect that it is possible to further enhance the effect of relaxing the stress by increasing the length z of the slit S in the second direction. In FIG. 9, the length z of the slit S in the second direction is indicated by the multiplier of the length c of the first land L1 in the second direction.

### Third Embodiment

A third embodiment of the mounting board 1 will be described. The third embodiment will be described focusing on a configuration different from the first embodiment and the second embodiment.

As shown in FIG. 3, the mounting board 1 may further include a third wiring pattern P3 in addition to the first wiring pattern P1 and the second wiring pattern P2, and may include a third land L3 and a fourth land L4 for connecting the pair of external electrodes of the multilayer ceramic capacitor to the second wiring pattern P2 and the third wiring pattern P3, respectively. In the mounting board 1, the first external electrode and the second external electrode of the first multilayer ceramic capacitor are respectively connected to the first land L1 and the second land L2 for connecting the first wiring pattern P1 and the second wiring pattern P2, and the third external electrode and the fourth external electrode of the second multilayer ceramic capacitor are respectively connected to the third land L3 and the fourth land L4 for connecting the second wiring pattern P2 and the third wiring pattern P3.

Both the first multilayer ceramic capacitor and the second multilayer ceramic capacitor described above have the same configuration as the multilayer ceramic capacitor 10 shown in FIG. 5. The first multilayer ceramic capacitor includes a first external electrode and a second external electrode corresponding to the first external electrode 31 and the second external electrode 32 of FIG. 5, and the second multilayer ceramic capacitor includes a third external electrode and a fourth external electrode corresponding to the first external electrode 31 and the second external electrode 32 in FIG. 5.

In the mounting board 1 shown in FIG. 3, when the power supply potential is supplied to the second wiring pattern P2, the ground potential can be supplied to the first wiring pattern P1 and the third wiring pattern P3. In addition, when the power supply potential is supplied to the first wiring pattern P1 or the third wiring pattern P3 and the ground potential is supplied to the third wiring pattern P3 or the first wiring pattern P1, two multilayer ceramic capacitors can be arranged in series between the power supply potential and the ground potential, such that it is possible to increase the breakdown voltage.

The third wiring pattern P3 may have the same shape as the first wiring pattern P1 or the second wiring pattern P2. In addition, the slit S can be provided similarly to the first wiring pattern P1 and the like.

Although embodiments of the present invention have been described above, the present invention is not limited to the embodiments, and can be implemented in various modes without departing from the gist of the present invention. The present invention includes the following combinations.

<1>

A mounting board includes: two wiring patterns for respectively supplying a ground potential and a power supply potential; and two lands for connecting each of a pair of terminals of a capacitor to a corresponding one of the two wiring patterns, in which,
in a plan view from a direction perpendicular to a surface of the mounting board, when a direction connecting centers of the two lands is defined as a first direction and a direction perpendicular to the first direction is defined as a second direction, a slit is provided in a first wiring pattern, a length of the slit in the second direction is longer than a length of a first land in the second direction, a length of the slit in the first direction is longer than a length of the first land in the first direction, a distance between an end portion among both end portions of the slit in the first direction that is adjacent to the first land and an end portion among both end portions of the first wiring pattern in the first direction that is adjacent to the first land is shorter than the length of the first land in the first direction, and the first wiring pattern has a linear end portion along the second direction, a length of the linear end portion is equal to or longer than the length of the first land in the second direction, and the linear end portion is in contact with the first land.
   <2>

In the mounting board as described in <1>, a recessed portion is provided in the first wiring pattern, and at least a portion of the first land is provided in the recessed portion.

<3>

In the mounting board as described in <1> or <2>, the length of the slit in the second direction is two times or more the length of the first land in the second direction.

<4>

In the mounting board as described in any one of <1> to <3>, the slit is provided in a second wiring pattern.

<5>

In the mounting board as described in any one of <1> to <4>, a third wiring pattern is provided, and two lands for connecting a pair of external electrodes of a multilayer ceramic capacitor to a second wiring pattern and the third wiring pattern, respectively, are provided.

<6>

A mounting configuration includes: the mounting board as described in any one of <1> to <4>; and a multilayer ceramic capacitor including a first external electrode and a second external electrode, in which the first external electrode is connected to the first land and the second external electrode is connected to a second land.

<7>

A mounting configuration includes: the mounting board as described in <5>; a multilayer ceramic capacitor including a first external electrode and a second external electrode; and a multilayer ceramic capacitor including a third external electrode and a fourth external electrode, in which the first external electrode and the second external electrode are respectively connected to the first land and the second land, and the third external electrode and the fourth external electrode are respectively connected to a third land and a fourth land.

### EXPLANATION OF REFERENCE NUMERALS

1 mounting board
2 recessed portion
10 multilayer ceramic capacitor
20 multilayer body
31 first external electrode
32 second external electrode
Es linear end portion
L1 first land
L2 second land
L3 third land
L4 fourth land
P1 first wiring pattern
P2 second wiring pattern
P3 third wiring pattern
Pe end portion
S slit
Se end portion
a, b, c, y, z length
x distance

1. A mounting board comprising:
a first wiring pattern and a second wiring pattern for respectively supplying a ground potential and a power supply potential; and
a first land and a second land, the first land configured to connect a first terminal of a capacitor to the first wiring pattern and the second land configured to connect a second terminal of the capacitor to the second wiring pattern, wherein,
in a plan view from a direction perpendicular to a surface of the mounting board,
when a direction connecting centers of the first land and the second land is defined as a first direction and a direction perpendicular to the first direction is defined as a second direction,
a slit is in a first wiring pattern,
a length of the slit in the second direction is longer than a length of a first land in the second direction,
a length of the slit in the first direction is longer than a length of the first land in the first direction,
a distance between an end portion of the slit in the first direction adjacent to the first land and an end portion of the first wiring pattern in the first direction adjacent to the first land is shorter than the length of the first land in the first direction, and
the first wiring pattern has a linear end portion along the second direction, a length of the linear end portion is equal to or longer than the length of the first land in the second direction, and the linear end portion is in contact with the first land.

2. The mounting board according to claim 1, wherein a recessed portion is provided in the first wiring pattern, and at least a portion of the first land is provided in the recessed portion.

3. The mounting board according to claim 1, wherein the length of the slit in the second direction is two times or more the length of the first land in the second direction.

4. The mounting board according to claim 1, further comprising a second slit in the second wiring pattern.

5. The mounting board according to claim 4, wherein the second slit has a length in the second direction that is longer than a length of the second land in the second direction.

6. The mounting board according to claim 1, further comprising:
a third wiring pattern;
a third land electrically connected to the second wiring pattern; and
a fourth land electrically connected the third wiring pattern, respectively, are provided.

7. A mounting configuration comprising:
the mounting board according to claim 1; and
a multilayer ceramic capacitor including a first external electrode and a second external electrode,
wherein
the first external electrode is connected to the first land and the second external electrode is connected to the second land.

8. A mounting configuration comprising:
the mounting board according to claim 6;
a first multilayer ceramic capacitor including a first external electrode and a second external electrode; and
a second multilayer ceramic capacitor including a third external electrode and a fourth external electrode, wherein
the first external electrode and the second external electrode are respectively connected to the first land and the second land, and
the third external electrode and the fourth external electrode are respectively connected to the third land and the fourth land.

9. The mounting configuration according to claim 8, wherein the first multilayer ceramic capacitor and the second multilayer ceramic capacitor are electrically connected in series.

10. The mounting board according to claim 1, wherein the first wiring pattern is a ground wiring pattern.

11. The mounting board according to claim 1, wherein the first wiring pattern is a solid wiring pattern.

12. The mounting board according to claim 1, wherein the slit includes a region within the first wiring pattern that is void of conductive material.

13. The mounting board according to claim 1, wherein the slit is a through-hole that penetrates the mounting board.

14. The mounting board according to claim 1, wherein the slit has a quadrangular shape in the plan view.

15. The mounting board according to claim 1, wherein the first land and the second land each have a rectangular shape in the plan view.

16. The mounting board according to claim 1, wherein the length of the slit in the second direction is three times or more the length of the first land in the second direction.

17. A mounting configuration comprising:
the mounting board according to claim 1; and
a capacitor having its first and second terminals respectively connected to the first land and the second land.
